(19) United States
(12) Patent Application Publication
(10) Pub. No.: US 2013/0240849 A1
(43) Pub. Date: Sep. 19, 2013

(54) ORGANIC ELECTROLUMINESCENT APPARATUS

(71) Applicant: AU OPTRONICS CORPORATION, Hsinchu (TW)

(72) Inventors: Po-Hsuan Chiang, New Taipei City (TW); Chung-Chia Chen, New Taipei City (TW); Chun-Liang Lin, New Taipei City (TW)

(73) Assignee: Au Optronics Corporation, Hsinchu (TW)

(21) Appl. No.: 13/783,396

(22) Filed: Mar. 4, 2013

(30) Foreign Application Priority Data
Mar. 19, 2012 (TW) 101109336

(51) Int. Cl. H01L 51/50

(52) U.S. Cl. CPC H01L 51/504
USPC 257/40

(57) ABSTRACT

An organic electroluminescent apparatus is provided. A first electrode layer is disposed above a substrate. A first color luminescent layer is disposed above the first electrode layer. A second color luminescent layer is disposed above the first color luminescent layer. A third color luminescent layer is disposed on the second color luminescent layer. A first color light emitted from the first color luminescent layer, a second color light emitted from the second color luminescent layer and a third color light emitted from the third color luminescent layer are mixed to form a white light. A first fluorescent layer is disposed on the substrate. The first fluorescent layer is excited by the first color light so as to emit the second color light, the third color light or a fourth color light.

### CROSS-REFERENCE TO RELATED APPLICATION

This application claims the priority benefit of Taiwan application serial no. 101109336, filed on Mar. 19, 2012. The entirety of the above-mentioned patent application is hereby incorporated by reference herein and made a part of this specification.

### TECHNICAL FIELD

The disclosure relates to a luminescent apparatus, more particularly to an organic electroluminescent apparatus.

### BACKGROUND

An organic electroluminescent apparatus is an emissive display apparatus. Since an organic electroluminescent apparatus possesses the characteristics of wide viewing angle, high response speed (approximately 100 times faster than that of liquid crystals), light weight, adaptability to miniature and low-profile design of the corresponding hardware equipment, high light emitting efficiency, high color rendering index and plane light source, it has a great potential to become the new flat display panel of the next generation.

The current products mostly apply the tandem device structure to increase the efficiency and lifetime of an organic electroluminescent device. The tandem device structure relies on a connecting layer to connect two or more luminescent devices to achieve the summation of lifetimes and efficiencies. In application, a fluorescent material is mostly used in a blue light device as the blue luminescent material. Currently, the external quantum efficiency of a blue light device may reach 5%. Moreover, a higher efficiency phosphorous material is mostly used in a red light device and a green light device. Currently, the external quantum efficiency of a red light device and a green light device may reach 16%. After stacking the blue light device, the red light device and the green light device, an organic electroluminescent device having a white light frequency spectrum with high color rendering index and high color temperature is attained.

However, the white light temperature (approximately 5000K) emitted by the above-mentioned organic electroluminescent device tends to be high. If a low-temperature, white light organic electroluminescent device is to be fabricated, the efficiency of the blue light device has to be lower or the efficiency of the red light device and the green light device has to be increased. However the efficiency of the red light and green light device (16%) is already approaching the theoretical limit (about 20%). Accordingly, further increasing the efficiency of the red and green light is difficult. The current approach for realizing the low temperature white light is to apply an optical structure to lower the blue light efficiency. However, according to the above approach, a portion of the light emitting efficiency of the blue light device is lost. Ultimately, the efficiency of the overall organic electroluminescent apparatus is lower.

### SUMMARY

An exemplary embodiment of the disclosure provides an organic electroluminescent apparatus, wherein the efficiency problem of the conventional tandem light emitting device and the color adjustment problem may be resolved.

An exemplary embodiment of the disclosure provides an organic electroluminescent apparatus. The above-mentioned organic electroluminescent apparatus includes a substrate, a first electrode layer, a first color luminescent layer, a second color luminescent layer, a second electrode layer and a first fluorescent layer. The substrate is configured at a first light emitting side of the organic electroluminescent apparatus. The first electrode layer is configured above the substrate. The first color luminescent layer is configured above the first electrode layer. The second color luminescent layer is configured above the first color luminescent layer. The third color luminescent layer is configured above the second color luminescent layer. A first color light emitted from the first color luminescent layer, a second color light emitted from the second color luminescent layer and a third color light emitted from the third color luminescent layer are mixed so as to form a white light. The second electrode layer is positioned on the third color luminescent layer. The first fluorescent layer is configured on the substrate. The first color light emitted from the first color luminescent layer excites the first fluorescent layer to emit the second color light, the third color light or a fourth color light.

An exemplary embodiment of the disclosure provides an organic electroluminescent apparatus. The above-mentioned organic electroluminescent apparatus includes a substrate, a first electrode layer, a first color luminescent layer, a second color luminescent layer, a third color luminescent layer, a second electrode layer and a fluorescent layer. The first electrode layer is configured above the substrate. The first color luminescent layer is configured above the first electrode layer. The second color luminescent layer is configured above the first color luminescent layer. The third color luminescent layer is configured above the second color luminescent layer. A first color light emitted from the first color luminescent layer, a second color light emitted from the second color luminescent layer and a third color light emitted from the third color luminescent layer are mixed to form a white light. The second electrode layer is positioned on the third color luminescent layer and is configured at one light emitting side of the organic electroluminescent apparatus. The fluorescent layer is configured on the second electrode layer, wherein the first color light emitted from the first color luminescent layer excites the fluorescent layer to emit the second color light, the third color light or a fourth color light.

According to the organic electroluminescent apparatus of the disclosure, the fluorescent layer is coated on the light emitting side of the organic electroluminescent apparatus. A portion of the first color light emitted from the first color luminescent layer can excite the fluorescent layer to emit the color light. Moreover, the color light emitted from the fluorescent layer using difference fluorescent materials mix with the first color light, the second color light and the third color light so as to form a white light having a lower color temperature. Hence, the adjustment of the color temperature of white light is achieved. Accordingly, the organic electroluminescent apparatus of the disclosure is provided with a fluorescent layer using different fluorescent materials that mix to form white lights of different color temperatures. The luminescent efficiency of the first color luminescent layer is effectively used.

The disclosure and certain merits provided by the application can be better understood by way of the following exemplary embodiments and the accompanying drawings, which are not to be construed as limiting the scope of the disclosure.

### BRIEF DESCRIPTION OF THE DRAWINGS

FIG. 1 is a schematic, cross-sectional view diagram of an organic electroluminescent apparatus according to a first exemplary embodiment of the disclosure.

FIG. 2 is a schematic, cross-sectional view diagram of an organic electroluminescent apparatus according to a second exemplary embodiment of the disclosure.

FIG. 3 is a schematic, cross-sectional view diagram of an organic electroluminescent apparatus according to a third exemplary embodiment of the disclosure.

FIG. 4 is a schematic, cross-sectional view diagram of an organic electroluminescent apparatus according to a fourth exemplary embodiment of the disclosure.

FIG. 5 is a schematic, cross-sectional view diagram of an organic electroluminescent apparatus according to a fifth exemplary embodiment of the disclosure.

FIG. 6 is a schematic, cross-sectional view diagram of an organic electroluminescent apparatus according to a sixth exemplary embodiment of the disclosure.

FIG. 7 is a schematic, cross-sectional view diagram of an organic electroluminescent apparatus according to a seventh exemplary embodiment of the disclosure.

FIG. 8 is a schematic, cross-sectional view diagram of an organic electroluminescent apparatus according to an eighth exemplary embodiment of the disclosure.

FIG. 9 is a schematic, cross-sectional view diagram of an organic electroluminescent apparatus according to a ninth exemplary embodiment of the disclosure.

FIG. 10 is a schematic, cross-sectional view diagram of an organic electroluminescent apparatus according to a tenth exemplary embodiment of the disclosure.

FIG. 11 is a schematic, cross-sectional view diagram of an organic electroluminescent apparatus according to an eleventh exemplary embodiment of the disclosure.

FIG. 12 is a schematic, cross-sectional view diagram of an organic electroluminescent apparatus according to a twelfth exemplary embodiment of the disclosure.

FIG. 13 is a schematic, cross-sectional view diagram of an organic electroluminescent apparatus according to a thirteenth exemplary embodiment of the disclosure.

FIG. 14 is a schematic, cross-sectional view diagram of an organic electroluminescent apparatus according to a fourteenth exemplary embodiment of the disclosure.

FIG. 15 is a diagram showing the relationships between the luminescent intensity and wave length of comparative example 1 and the exemplary embodiment of the disclosure.

### DETAILED DESCRIPTION OF DISCLOSED EMBODIMENTS

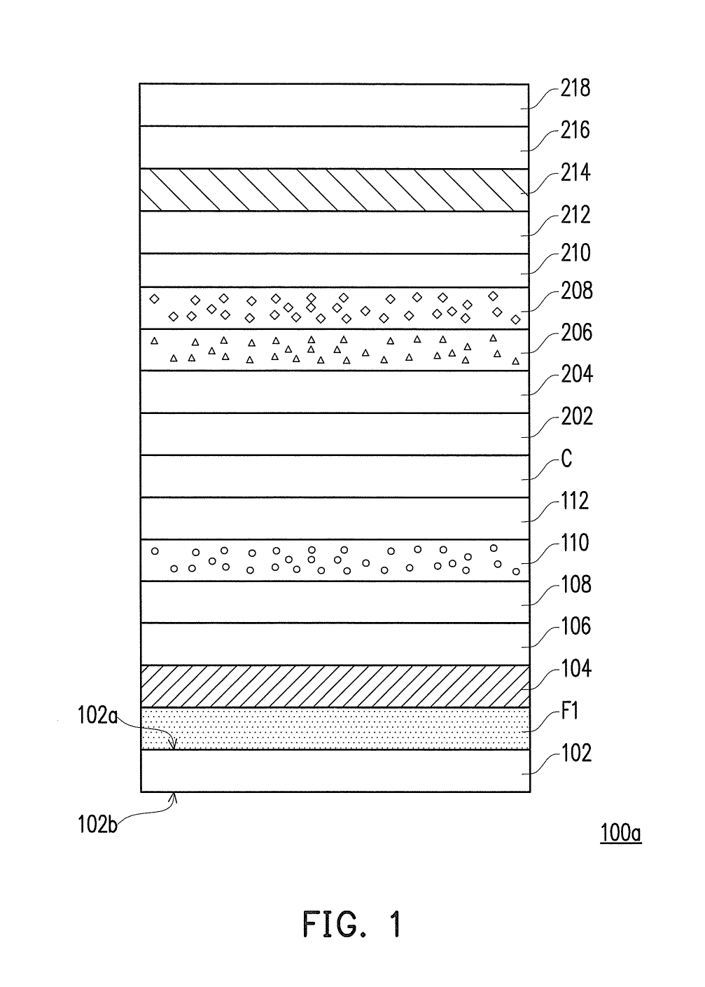

FIG. 1 is a schematic cross-sectional view diagram of an organic electroluminescent apparatus according to a first exemplary embodiment of the disclosure. Referring to FIG. 1, the organic electroluminescent apparatus according to the first exemplary embodiment includes a substrate 102, a first electrode layer 104, a first color luminescent layer 110, a second color luminescent layer 206, a third color luminescent layer 208, a second electrode layer 214 and a first fluorescent layer F1.

The substrate 102 is a transparent substrate, and the substrate 102 is constituted with a material that includes, for example, glass, organic polymer and other appropriate transparent materials. In this exemplary embodiment, the substrate 102 is configured at a first light emitting side of the organic electroluminescent apparatus 100a.

The first electrode layer 104 is configured above the substrate 102. According to an exemplary embodiment, the first electrode layer 104 is a transparent electrode layer, and first electrode layer 104 is constituted with a material that includes, for example, metal oxide, such as indium-tin oxide (ITO), indium-zinc oxide (IZO) gallium-zinc oxide (GZO), zinc-tin oxide (ZTO), or other metal oxide materials.

The first color luminescent layer 110 is configured above the first electrode 104. The first color luminescent layer 110 emits a first color light. According to the exemplary embodiment, the first color luminescent layer 110 may be a blue color luminescent layer. Accordingly, the first color light is a blue light. The blue luminescent layer may be a blue fluorescent material or a blue phosphor material. In application, limited by the color of the light and the life time of the material, the first color luminescent layer 110 is constructed with a blue fluorescent material with a longer life time, and the external quantum efficiency of the blue fluorescent material is about 5%.

The second color luminescent layer 206 is configured above the first color luminescent layer 110. The second color luminescent layer 206 emits a second color light. According to an exemplary embodiment, the second color luminescent layer 206 may be a red luminescent layer. Therefore, the second color light is a red light. The red luminescent layer may be a red fluorescent material or a blue phosphor material. In application, the second color luminescent layer 206 includes a red phosphor material having a higher efficiency.

The third color luminescent layer 208 is configured above the second color luminescent layer 206. The third color luminescent layer 208 emits a third color light. According to the exemplary embodiment of the disclosure, the third color luminescent layer 208 may be a green luminescent layer. Therefore, the third color light is a green light. The green luminescent layer may be a green fluorescent material or a green phosphor material. In application, the third color luminescent layer 208 of this exemplary embodiment applies the green phosphor material having a higher efficiency. Moreover, the sum of the external quantum efficiencies of the second color luminescent layer 206 and the third color luminescent layer 208 is about 16%.

It is worthy to note that although the third color luminescent layer 208 in the exemplary embodiment is positioned above the second color luminescent layer 206, the embodiment is presented by way of example and not by way of limitation. According to other exemplary embodiments, the second color luminescent layer 206 may be disposed on the third color luminescent layer 208 (alternatively speaking, the positions of the second color luminescent layer 206 and the third color luminescent layer 208 can be exchanged).

According to the above disclosure, the first color light emitted from the first color luminescent layer 110, the second color light emitted from the second color luminescent layer 206, and the third color light emitted from the third color luminescent layer 208 are mixed so as to form a white light.

The second electrode layer 214 is positioned above the third color luminescent layer 208. According to the exemplary embodiment, the second electrode layer 214 includes a metal electrode material, such as aluminum, aluminum/lithium alloy, magnesium/silver alloy or other metal materials.

The first fluorescent layer F1 is configured on an internal surface of the substrate 102. According to this exemplary embodiment, the fluorescent material of the first fluorescent layer F1 includes silicate, yttrium aluminum garnet (YAG, Y₃Al₂(AlO₄)₃), green fluorescent powders, red fluorescent powders, lutetium aluminum garnet (LuAG, Lu₃Al₂(AlO₄)₃), terbium aluminum garnet (TbAG, Tb₃Al₂(AlO₄)₃) or other appropriate fluorescent materials. The thickness of the first fluorescent layer F1 is about 0.1 μm to 1 mm. The concentration of the fluorescent material in the first fluorescent layer F1 is about 0.1% to 3%.

It should be noted that the first color light emitted from the first color luminescent layer 110 may excite the first fluorescent layer F1 to emit the second color light, the third color light or a fourth color light. More specifically, the first fluorescent layer F1, after being excited by the first color light (blue light), may emit a red light, a green light or a mixed color light of the red light and the green light. It should also be noted that this embodiment is presented by way of example and not by way of limitation. The type of the fourth color light may be selected according to the color temperature of the white light of the organic electroluminescent apparatus. Alternatively speaking, one of ordinary skill in the art may determine the type of white light emitted from the excited first fluorescent layer based on the white light color temperature emitted from the first light emitting side. In one exemplary embodiment, after the first fluorescent layer is excited by the first color light (for example, a blue light), the first fluorescent layer emits both the red light and the green light.

Moreover, the color temperature of the white light formed by the mixing of the first color light, the second color light and the third color light is at about 5000K. When the above white light penetrates through the first fluorescent layer F1, the part of the first color light that constitutes the white light excites the first fluorescent layer F1 to emit the second color light, the third color light or the fourth color light. Accordingly, the intensity of the first color light in the original white light correspondingly reduces, and the intensity of the second color light, third color light or the fourth color light correspondingly increases. Hence, the color temperature of the white light emitted from the first light emitting side can be adjusted.

It is worthy to notice that, in this exemplary embodiment, a portion of the first color light is transformed into the second color light, the third color light or the fourth color light to achieve the adjustment of the white light temperature. Since the adjustment of the white light temperature is not achieved via the suppression of the luminous intensity of the first color light (the blue light), the first color light (the blue light) can be completely used according to the method of this exemplary embodiment; hence, the light emitting efficiency of the organic electroluminescent apparatus of the exemplary embodiment of the disclosure is enhanced. Additionally, by altering one of the parameters of the type of the fluorescent material, the thickness and the concentration of the fluorescent material of the first fluorescent layer F1, the color temperature of the white light can be further adjusted.

In this exemplary embodiment, the organic electroluminescent apparatus 100a further includes a charge generation layer C. The charge generation layer C is positioned between the first color luminescent layer 110 and the second color luminescent layer 206. The charge generation layer C is used to connect the luminescent unit foamed by the first color luminescent layer 110 and the luminescent units formed by the second color luminescent layer 206 and the third color luminescent layer 208.

In order to enhance the electron-hole combination rate of the first color luminescent layer 110 for increasing the light emitting efficiency, a first hole injection layer 106 is typically configured between the first electrode layer 104 and the first color luminescent layer 110; a first hole transmission layer 108 is configured between the first hole injection layer 106 and the first color luminescent layer 110; and a first electron transmission layer 112 is configured between the charge generation layer C and the first color luminescent layer 110.

Similarly, in order to enhance the electron-hole combination rate of the second color luminescent layer 206 and the third color luminescent layer 208 for increasing their light emitting efficiency, a second hole injection layer 202 is typically configured between the second color luminescent layer 206 and the charge generation layer C; a second hole transmission layer 204 is configured between the second hole injection layer 202 and the second color luminescent layer 206; a second electron transmission layer 210 is configured between the third color luminescent layer 208 and the second electrode layer 214 layer; and a second electron injection layer 212 is configured between the second electron transmission layer 210 and the second electrode layer 214.

It is worthy to note that the invention is not limited to an organic electroluminescent device 100a being configured with the above-mentioned electron injection layer, electron transmission layer, hole injection layer and hole transmission layer. The invention is also not limited to an organic electroluminescent device 100a being configured with the number of layers of the above-mentioned electron injection layer, electron transmission layer, hole injection layer and hole transmission layer. In a practical application, the layer numbers of the electron injection layer, the electron transmission layer, the hole injection layer and the hole transmission layer are determined by the selected materials of the first electrode layer 104, the first color luminescent layer 110, the second color luminescent layer 206, the third color luminescent layer 208, the second electrode layer 214 and the charge generation layer C.

Moreover, the organic electroluminescent apparatus 100a further includes a top cap layer 216 covering the second electrode layer 214. The top cap layer 216 serves to strengthen the organic electroluminescent apparatus 100a.

Moreover, the organic electroluminescent apparatus 100a further includes a package cover panel 218. The package cover panel 218 covers the second electrode 214. Generally speaking, the package cover panel 218, in combination with an encapsulant (not shown), encapsulates the organic electroluminescent apparatus 100a. The package cover panel 218 strengthens the organic electroluminescent device 100a and provides a hermetic effect of preventing moisture and oxygen from entering into the organic electroluminescent device 100a.

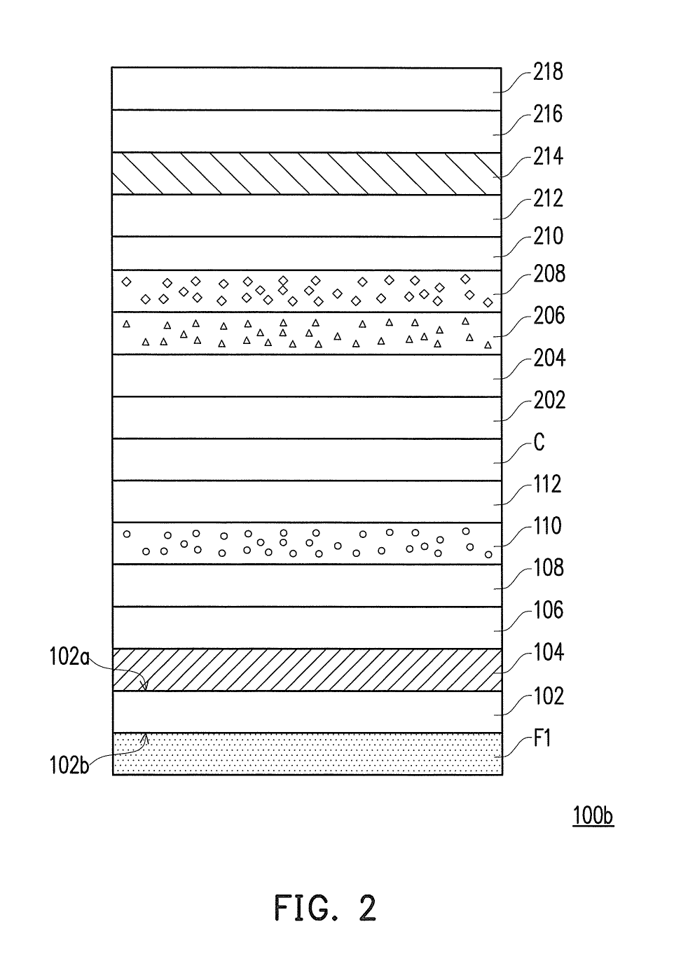

According to the first exemplary embodiment, the first fluorescent layer F1 is disposed on the internal surface 102a of the substrate 102, but the disclosure is not limited hereto. FIG. 2 is a schematic cross-sectional view diagram of an organic electroluminescent apparatus according to a second exemplary embodiment of the disclosure. Referring to FIG. 2, the organic electroluminescent apparatus 100b of the second exemplary embodiment is similar to the organic electroluminescent apparatus 100a of the first exemplary embodiment, and the difference between these two organic electroluminescent apparatuses lies in that the first fluorescent layer F1 of the organic electroluminescent apparatus 100b is disposed on an outer surface 102b of the substrate 102.

Moreover, the organic electroluminescent device 100a of the first exemplary embodiment and the organic electroluminescent device 100b of the second exemplary embodiment are both the bottom-emission type organic electroluminescent apparatus. The invention, however, is not limited to the bottom-emission type organic electroluminescent apparatus. The double-side emission type organic electroluminescent apparatus will be discussed in details in following exemplary embodiments.

Wherever possible, the same reference numbers are used to refer to the same or like parts in the previous and the following exemplary embodiments. Similar technical details, which can be referred to the previous exemplary embodiments for reference, will be omitted and not be further discussed.

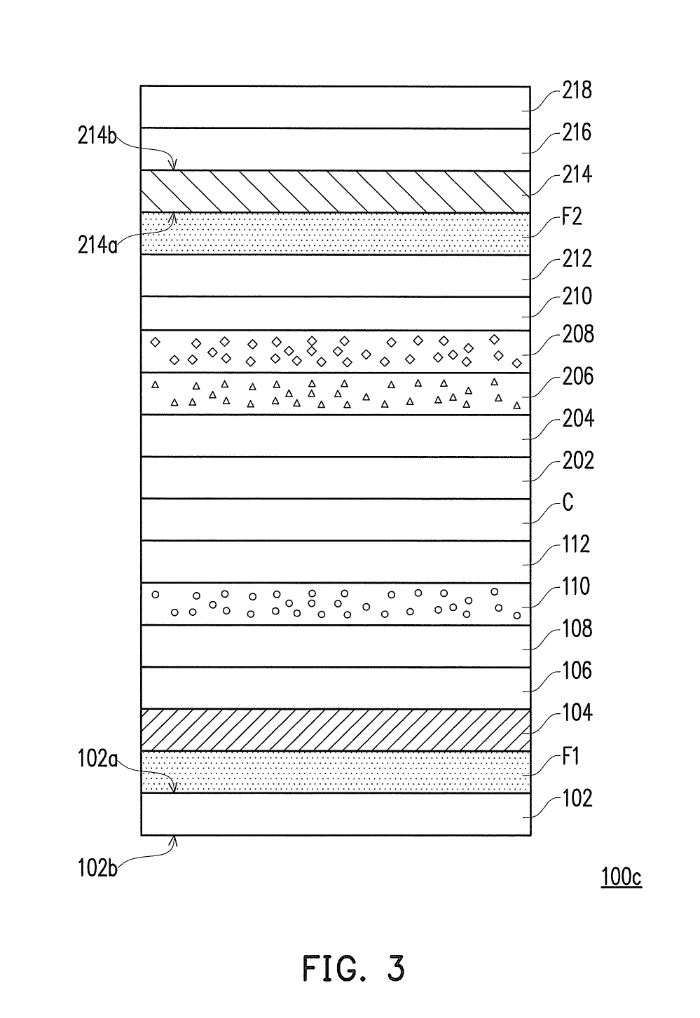

FIG. 3 is a schematic cross-sectional view diagram of an organic electroluminescent apparatus according to a third exemplary embodiment of the disclosure. Referring to FIG. 3, according to the third exemplary embodiment, the organic electroluminescent device 100c is a double-side emission type organic electroluminescent apparatus. The structures and the compositions of the organic electroluminescent apparatus 100c and the organic electroluminescent device 100a are similar. The major difference between the two devices lies in the organic electroluminescent device 100c further including a second fluorescent layer F2. The difference between the two devices is discussed hereinafter.

According to the third exemplary embodiment, the second electrode layer 214 is a transparent conductive layer, wherein the material of the second electrode layer 214 includes, but not limited to, metal oxide, such as indium-tin oxide (ITO), indium-zinc oxide (IZO), gallium-zinc oxide (GZO), zinc-tin oxide (ZTO) or a thin metal layer, etc. Since the organic electroluminescent device in this exemplary embodiment is a double-side emission type, the second electrode layer 214 is positioned at a second light emitting side of the organic electroluminescent device 100c.

The second fluorescent layer F2 is configured on the interior surface 214a of the second electrode layer 214. The fluorescent material of the second fluorescent layer F2 includes silicate, yttrium aluminum garnet (YAG, Y₃Al₂(AlO₄)₃), green fluorescent powders, red fluorescent powders, lutetium aluminum garnet (LuAG, Lu₃Al₂(AlO₄)₃), terbium aluminum garnet (TbAG, Tb₃Al₂(AlO₄)₃) or other appropriate fluorescent materials. The thickness of the second fluorescent layer F2 is about 0.1 μm to 1 mm. The concentration of the fluorescent material in the first fluorescent layer F1 is about 0.1% to 3%. Although in the organic electroluminescent apparatus, the second fluorescent layer F2 and the first fluorescent layer F1 are constituted with the same type of materials, the invention should not be construed as limited to the embodiments set forth herein. The first color light emitted from the first color luminescent layer 110 excites the second luminescent layer F2 to emit the second color light, the third color light or the fourth color light.

Accordingly, in the organic electroluminescent device 100c, the substrate 102 is positioned at the first light emitting side, and the second electrode layer 214 is positioned at the second light emitting side. The first fluorescent layer F1 is configured on the internal surface 102a of the substrate 102, the second fluorescent layer F2 is configured on the internal surface 214a of the second electrode layer 214. The first color light emitted from the first color luminescent layer 110 simultaneously excites the first fluorescent layer F1 and the second fluorescent layer F2 to emit different color lights.

Similar to the organic electroluminescent device 100a, the first color light emitted from the first color luminescent layer 110, the second color light emitted from the second color luminescent layer 206 and the third color light emitted from the third color luminescent layer 208 are mixed to form a white light. The organic electroluminescent apparatus 100c is a double-side emission type, and the first fluorescent layer F1 may adjust the white light color temperature emitted from the first light emitting side of the organic electroluminescent apparatus 100c. The second fluorescent layer F2 may adjust the white light temperature emitted form the second light emitting side of the organic electroluminescent apparatus 100c.

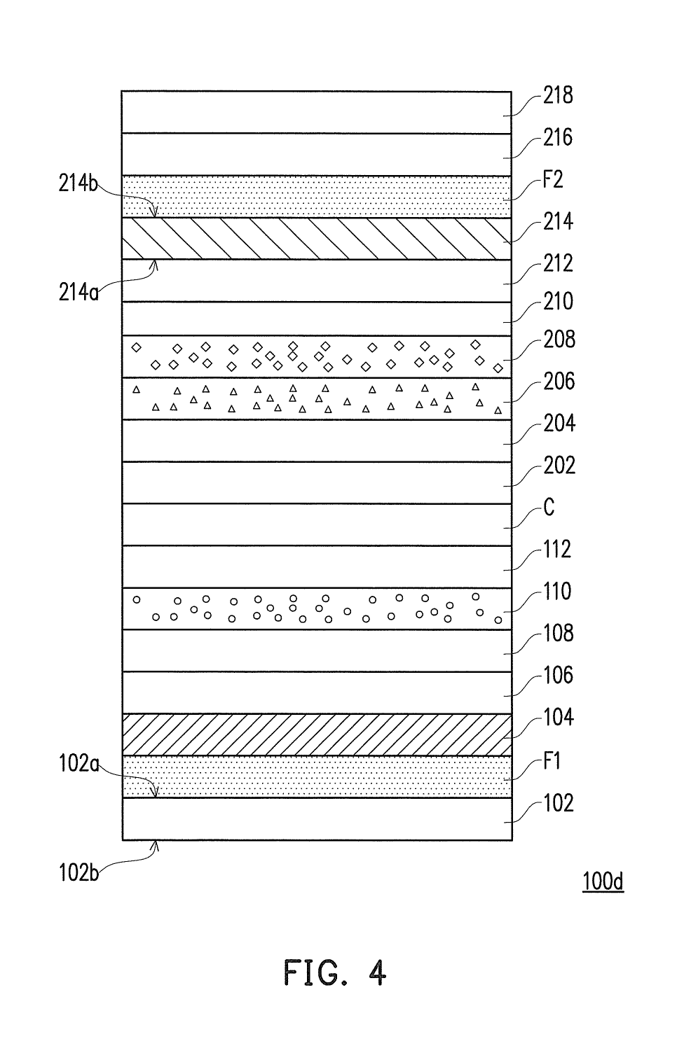

It is worthy to note that although in the organic electroluminescent apparatus 100c of the third exemplary embodiment, the first fluorescent layer F1 is positioned on the internal surface 102a of the substrate 102, the second fluorescent layer F2 is configured on the internal surface 214a of the second electrode layer 214, it is to be understood that these embodiment is presented by way of example and not by way of limitation. In the following disclosure, several exemplary embodiments are discussed. More particularly, the structures and the compositions of the organic electroluminescent apparatus 100d to 100j in the following exemplary embodiments as shown in FIGS. 4 to 10 are similar to those of the organic electroluminescent apparatus 100c. The differences between the apparatuses are discussed here-below.

FIG. 4 is a schematic cross-sectional view diagram of an organic electroluminescent apparatus according to a fourth exemplary embodiment of the disclosure. Referring to FIG. 4, in the organic electroluminescent device 100d, the first fluorescent layer F1 is configured on the internal surface 102a of the substrate 102, and the second fluorescent layer F2 is configured on the external surface 214b of the second electrode layer 214.

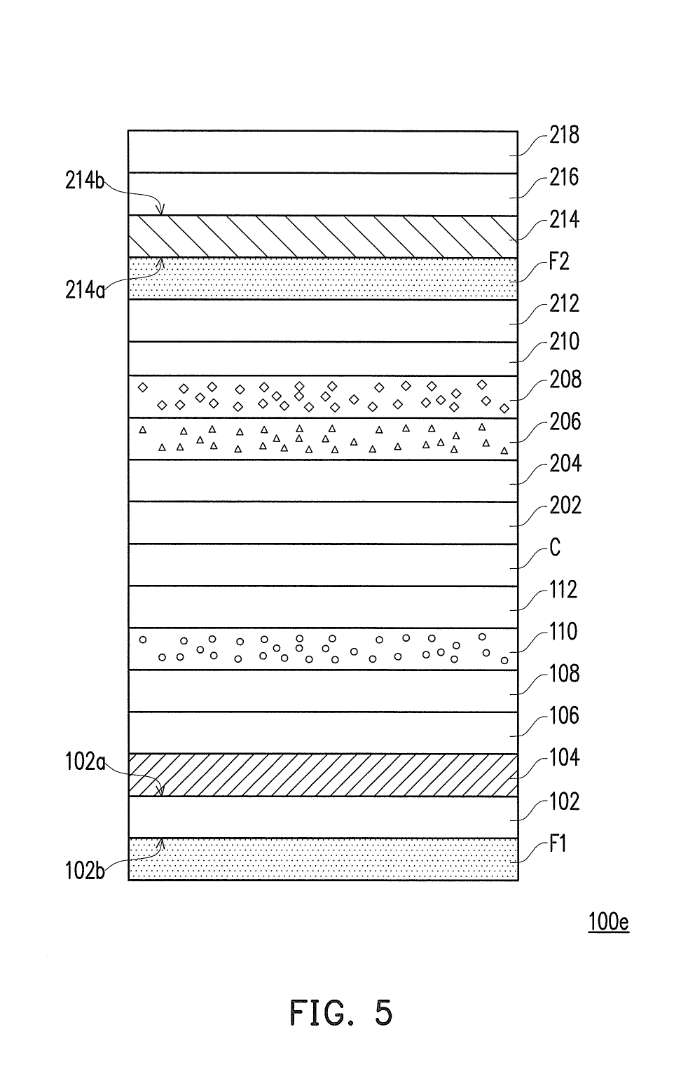

FIG. 5 is a schematic cross-sectional view diagram of an organic electroluminescent apparatus according to a fifth exemplary embodiment of the disclosure. Referring to FIG. 5, in the organic electroluminescent device 100e, the first fluorescent layer F1 is configured on the external surface 102b of the substrate 102, and the second fluorescent layer F2 is configured on the internal surface 214a of the second electrode layer 214.

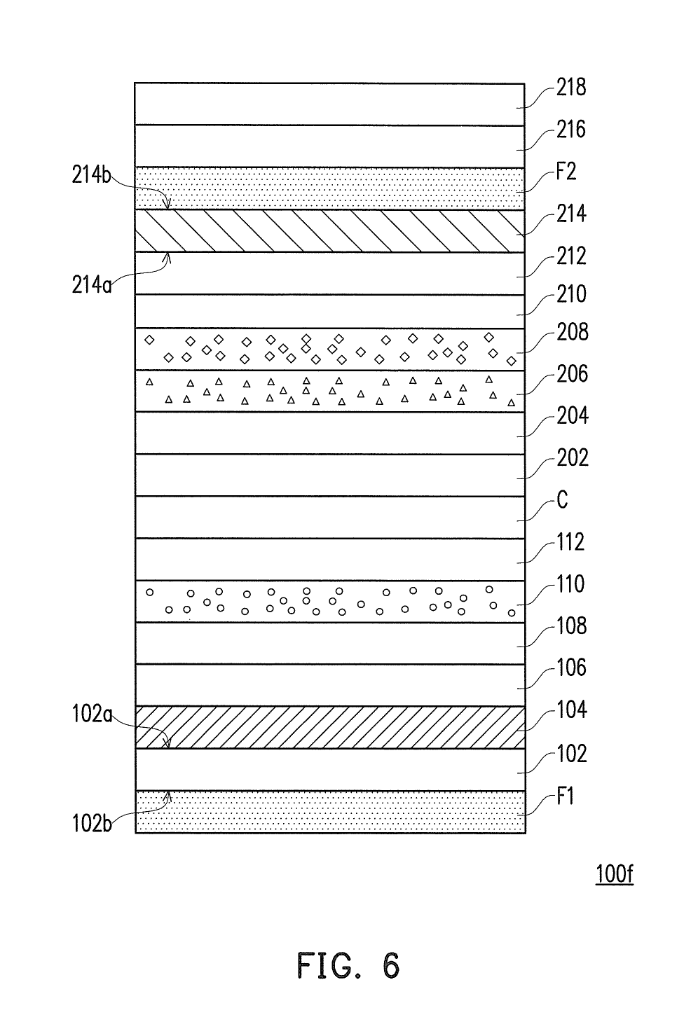

FIG. 6 is a schematic cross-sectional view diagram of an organic electroluminescent apparatus according to a sixth exemplary embodiment of the disclosure. Referring to FIG. 6, in the organic electroluminescent device 100f, the first fluorescent layer F1 is configured on the external surface 102b of the substrate 102, and the second fluorescent layer F2 is configured on the external surface 214b of the second electrode layer 214.

Moreover, the package cover panel 218 may also be configured at the light emitting side of the organic electroluminescent apparatus. Accordingly, the second fluorescent layer F2 may also be configured on the surface of the package cover panel 218, and several exemplary embodiments thereof are discussed in the following disclosure.

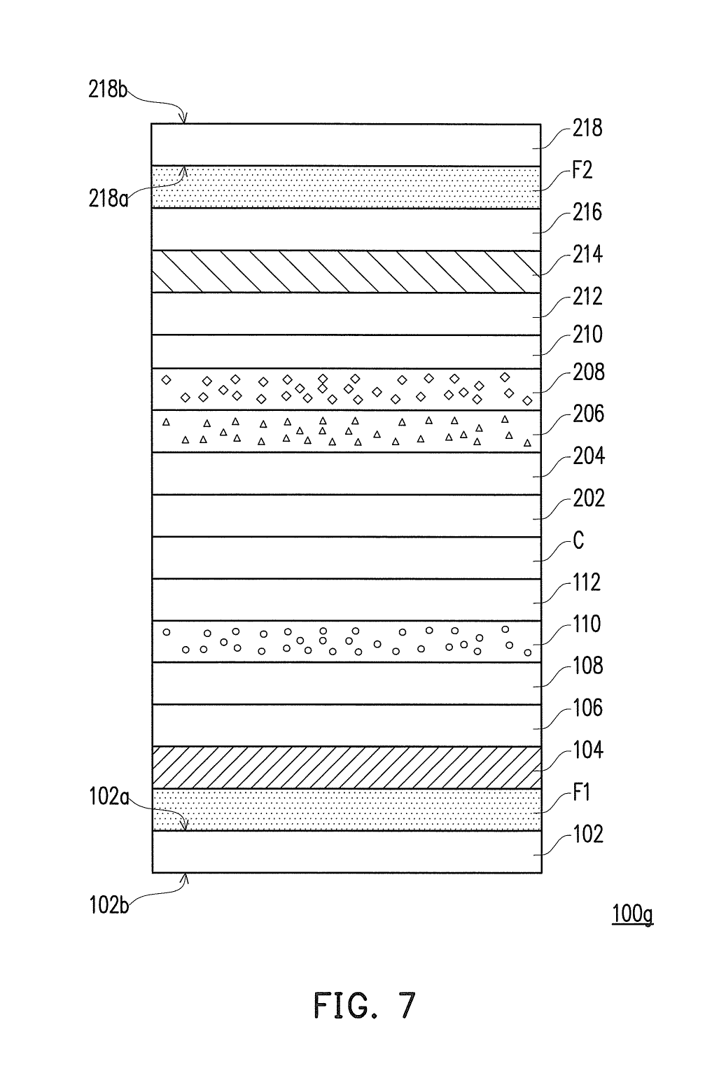

FIG. 7 is a schematic cross-sectional view diagram of an organic electroluminescent apparatus according to a seventh exemplary embodiment of the disclosure. Referring to FIG. 7, in the organic electroluminescent device 100g, the first fluorescent layer F1 is configured on the internal surface 102a of the substrate 102, and the second fluorescent layer F2 is configured on the internal surface 218a of the package cover panel 218.

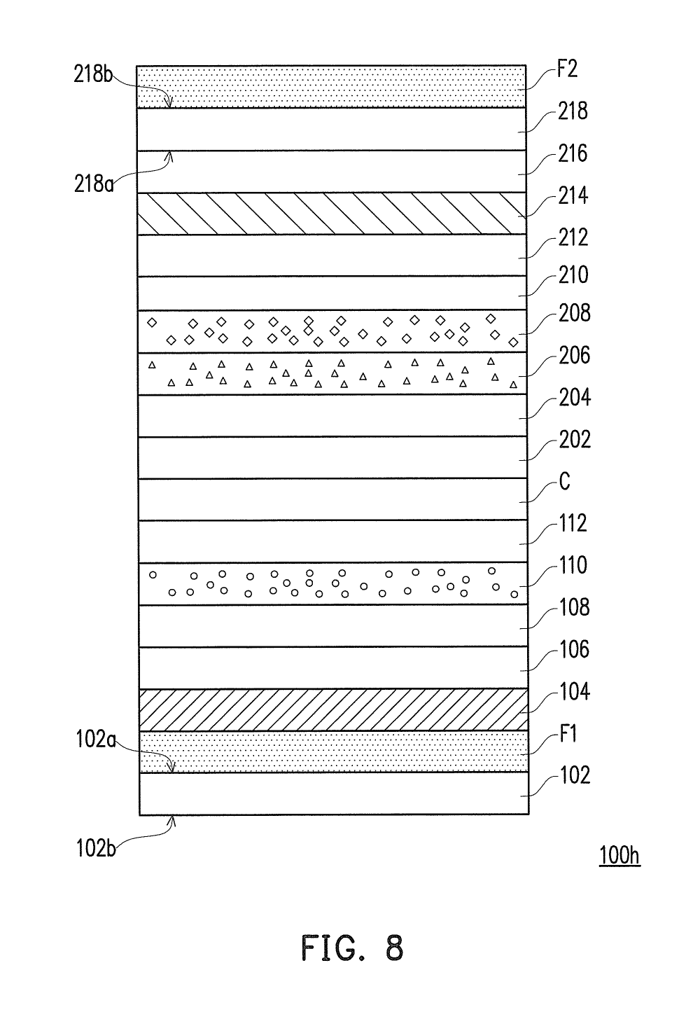

FIG. 8 is a schematic cross-sectional view diagram of an organic electroluminescent apparatus according to an eighth exemplary embodiment of the disclosure. Referring to FIG. 8, in the organic electroluminescent device 100h, the first fluorescent layer F1 is configured on the internal surface 102a of the substrate 102 and the second fluorescent layer F2 is configured on the external surface 218b of the package cover panel 218.

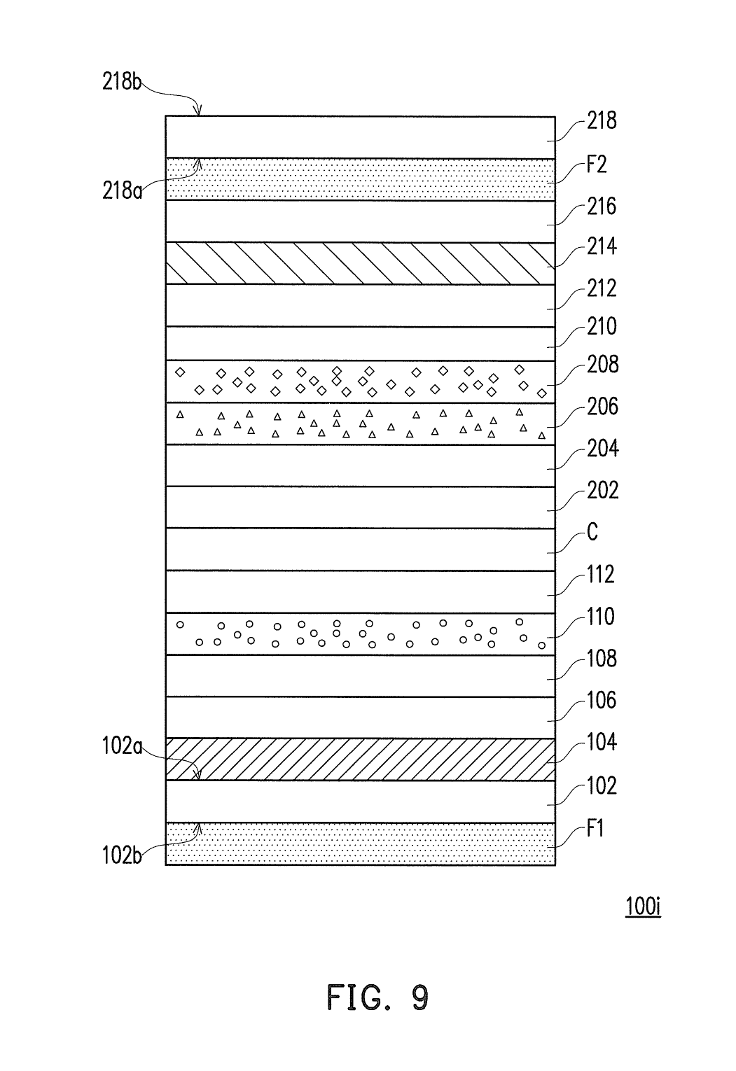

FIG. 9 is a schematic cross-sectional view diagram of an organic electroluminescent apparatus according to a ninth exemplary embodiment of the disclosure. Referring to FIG. 9, in the organic electroluminescent device 100i, the first fluorescent layer F1 is configured on the external surface 102b of the substrate 102 and the second fluorescent layer F2 is configured on the internal surface 218a of the package cover panel 218.

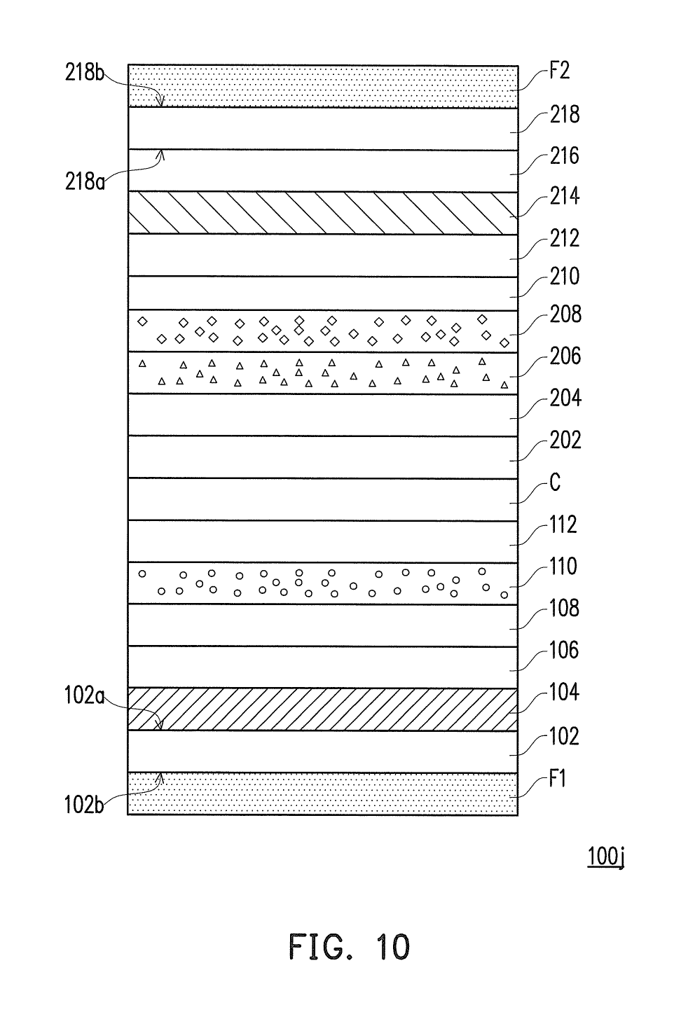

FIG. 10 is a schematic cross-sectional view diagram of an organic electroluminescent apparatus according to a tenth exemplary embodiment of the disclosure. Referring to FIG. 10, in the organic electroluminescent device 100j, the first fluorescent layer F1 is configured on the external surface 102b of the substrate 102 and the second fluorescent layer F2 is configured on the external surface 218b of the package cover panel 218.

Accordingly, the positions of the first fluorescent layer F1 and the second fluorescent layer F2 of the invention are not limited. As long as the first fluorescent layer F1 and the second fluorescent layer F2 are respectively configured on the light emitting sides of the organic electroluminescent apparatus, the variations of embodiments fall within the spirit and scope of the invention.

Moreover, in the following exemplary embodiments, the top emission type of organic electroluminescent apparatus is disclosed in details. It should be noted that wherever possible, the same reference numbers are used to refer to the same or like parts in the previous and the following exemplary embodiments. Similar technical details, which can be referred to the previous exemplary embodiment for reference, will also be omitted and not be further discussed.

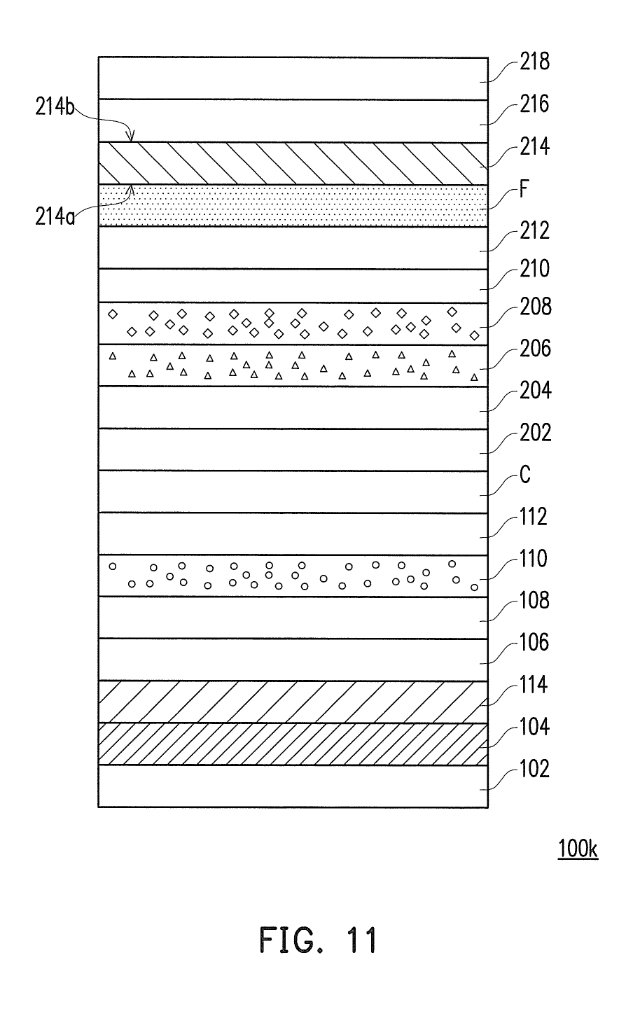

FIG. 11 is a schematic cross-sectional view diagram of an organic electroluminescent apparatus according to an eleventh exemplary embodiment of the disclosure. Referring to FIG. 11, the organic electroluminescent apparatus 100K in this exemplary embodiment is a top-emission type of organic electroluminescent apparatus, which includes a substrate 102, a first electrode layer 104, a first color luminescent layer 110, a second color luminescent layer 206, a third color luminescent layer 208, a second electrode layer 214 and a fluorescent layer F.

According to this exemplary embodiment, the first electrode layer 104 is configured on the substrate 102. The first color luminescent layer 110 is configured on the first electrode layer 104. The second color luminescent layer 206 is configured on the first color luminescent layer 110. The third color luminescent layer 208 is configured on the second color luminescent layer 206. The first color light emitted from the first color luminescent layer 100, the second color light emitted from the second color luminescent layer 206, and the third color light emitted from the third color luminescent layer 208 are mixed to foam a white light. The second electrode layer 214 is configured on the third color luminescent layer 208, wherein the second electrode layer 214 is configured at the light emitting side of the organic electroluminescent apparatus 100k. The fluorescent layer F is configured on the second electrode layer 214, wherein the first color light emitted from the first color luminescent layer 110 excites the fluorescent layer F to emit a second color light, a third color light, or a fourth color light.

More particularly, the structure and the light emitting theory of the organic electroluminescent device 100k and those of the organic electroluminescent device 100c of the third exemplary embodiment are similar, wherein the fluorescent layer F of the organic electroluminescent device 100k is substantially the same as that of the second fluorescent layer F2 of the organic electroluminescent apparatus 100c. Accordingly, the first color light can excite the fluorescent layer F to emit a color light for adjusting the color temperature of the white light.

Moreover, the difference between the organic electroluminescent apparatus 100k and the organic electroluminescent apparatus 100c lies in that the organic electroluminescent apparatus 100k does not include the first fluorescent layer F1 in the organic electroluminescent apparatus 100c. The organic electroluminescent apparatus 100k includes only one light emitting side.

In addition, the organic electroluminescent device 100k of this exemplary embodiment further includes a reflective electrode 114. The reflective electrode 114 covers the first electrode layer 104. The reflective electrode 114 is constituted with a material that includes a metal electrode material, such as aluminum, silver or other metal materials. According to this exemplary embodiment of the disclosure, the reflective electrode 114 reflects the first color light, the second color light, and the third color light to the light emitting side for enhancing the light emitting efficiency of the organic electroluminescent apparatus 100k.

Further, in other non-illustrated exemplary embodiments, the reflective electrode 114 may be disposed under the first electrode layer 104 or a substrate having a reflective function is directly used to reflect the color light without the application of the reflective electrode 114. Alternatively, the first electrode layer 104 and the reflective electrode 114 are constituted with the same material and provide the same reflective function; hence, an additional reflective electrode is not required.

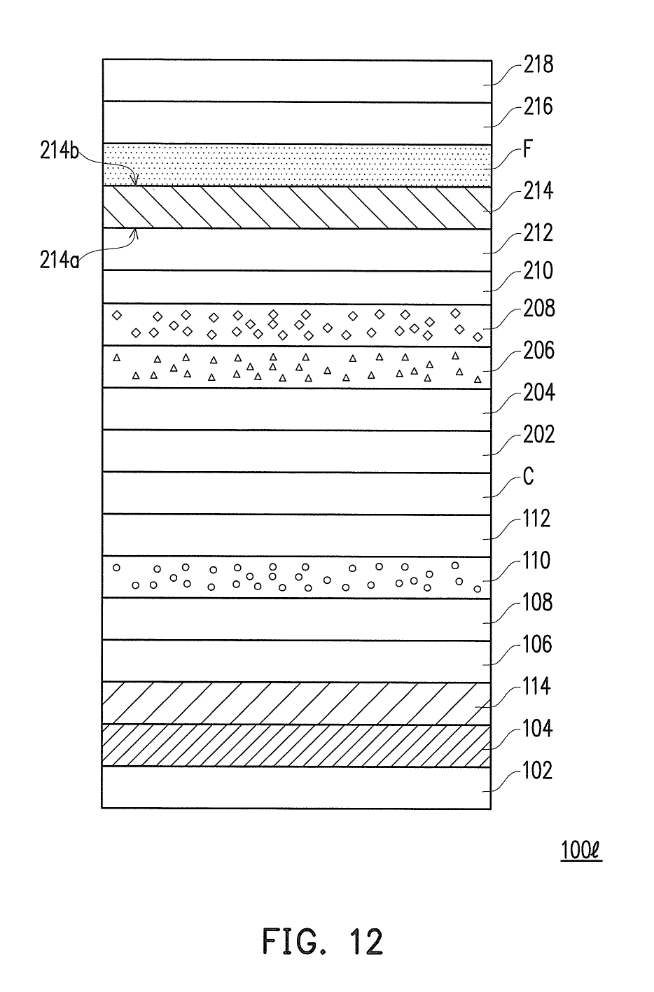

It is worthy to notice that, although the fluorescent layer F is configured on the internal surface 214a of the second electrode layer 214 according to the present exemplary embodiment, the invention should not be construed as limited to the embodiment set forth herein. In the organic electroluminescent device 100l of the twelfth exemplary embodiment of the disclosure, the fluorescent layer F is configured on the external surface 214b of the second electrode layer 214, as shown in FIG. 12.

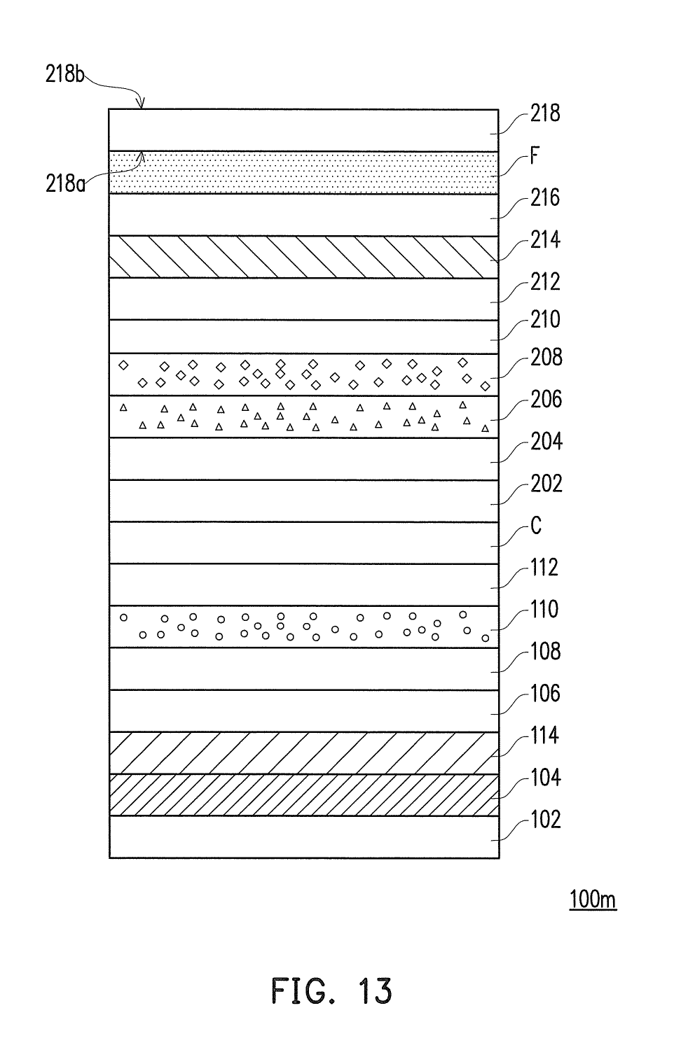

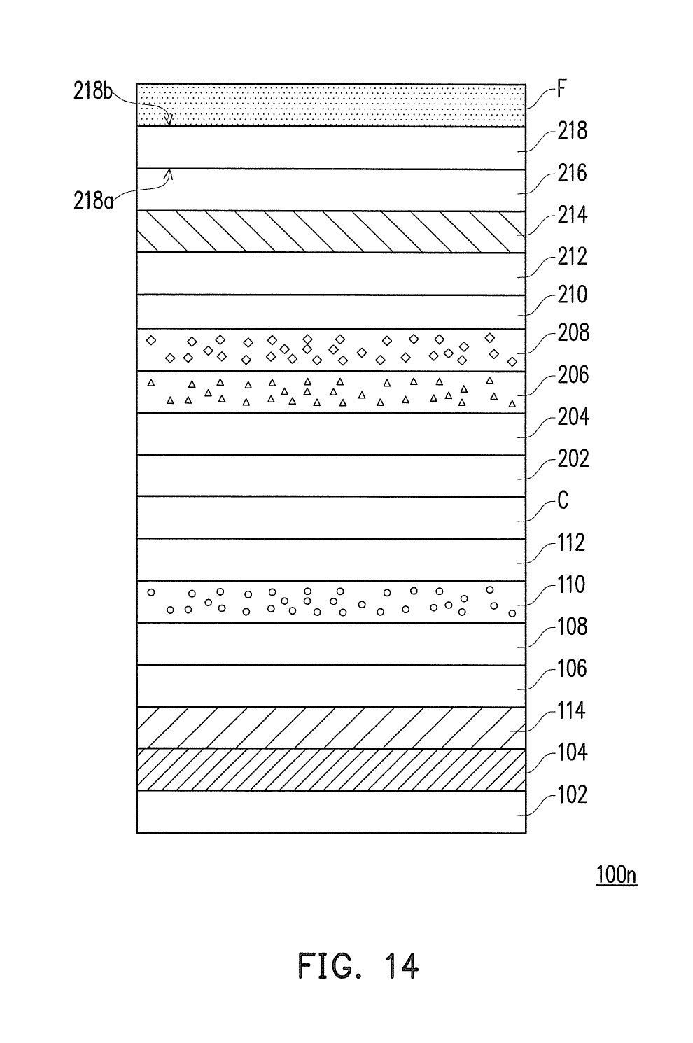

Further, the position of the fluorescent layer F of the invention should not be construed as limited to the embodiments set forth herein. In the organic electroluminescent apparatus 100m of the thirteenth exemplary embodiment of the disclosure, the fluorescent layer F may be configured on the internal surface 218a of the package cover panel 218, as shown in FIG. 13. In the organic electroluminescent apparatus 100n of the fourteenth exemplary embodiment of the disclosure, the fluorescent layer F is configured on the external surface 218b of the package cover panel 218, as shown in FIG. 14.

### EXAMPLE

The following examples and the comparative example are used to illustrate an organic electroluminescent apparatus of the disclosure having a more favorable light emitting efficiency.

In the organic electroluminescent apparatus of the example, a blue fluorescent material is used for the first color emitting layer, a red phosphor material is used for the second color emitting layer, a green phosphor material is used for the third color emitting layer, and the fluorescent layer is configured on an external surface of the substrate, as the structure shown in FIG. 2. The organic electroluminescent apparatus of comparative example 1 does not include a fluorescent layer shown in FIG. 2. The organic electroluminescent apparatus of comparative example 2 is further disposed with an optical structure in the apparatus shown in FIG. 2, but does not include the fluorescent layer shown in FIG. 2. The above optical structure may suppress the light emitting efficiency of the blue light luminescent layer.

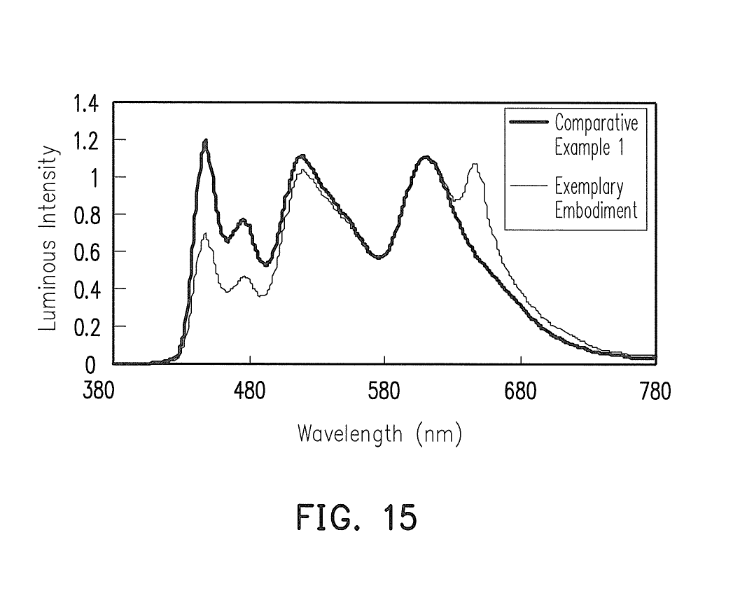

The light emitted from the organic electroluminescent layer of comparative example 1 and that of the example are subjected to light spectrum analysis. FIG. 15 is a diagram showing the relationships between the luminous intensity and wavelength of the organic electroluminescent apparatus of comparative example 1 and that of the example of the disclosure. Comparing to comparative example 1, in the light spectrum of the example as shown in FIG. 15, the intensity of the color light (blue light) at the wavelength between 430 nm to 490 nm is lower, while the intensity of the color light at the wavelength between 630 nm to 680 nm is higher. Accordingly, with the disposition of the fluorescent layer, the blue light is absorbed and other color lights are excited. Hence, the disposition of a fluorescent layer definitely achieves the adjustment of the color temperature of the white light emitted from organic electroluminescent apparatus.

Moreover, the external quantum efficiency (EQE) measurement is performed on the organic electroluminescent apparatuses in comparative example 1, comparative example 2, and the exemplary embodiment, and the results are summarized in Table 1.

TABLE 1

| | EQE (%) | EQE (%) of the | Total EQE (%) | |
|---|---|---|---|---|
| | of the | red luminescent | of the organic | |
| | blue lumi- | layer and | electro- | Color |
| | nescent | the blue lumi- | luminescent | Tempera- |
| | layer | nescent layer | apparatus | ture (K) |
| Comparative | 5 | 16 | 21 | 5000 |
| Example 1 | | | | |
| Comparative | 2 | 16 | 18 | 2800 |
| Example 2 | | | | |
| Example | 2 | 16 + | 20.4 | 2500~4000 |
| | | 3*0.8 = | | |
| | | 18.4 | | |

According to Table 1, comparing to comparative example 1, the external quantum efficiency of the first color luminescent layer in the example is reduced by 3%. Accordingly, the fluorescent layer in the example may absorb about 3% of the blue color light and transforms the blue color light emitted by the first color luminescent layer into at least one of the red color light and green color light, wherein the energy transformation efficiency ratio of the fluorescent layer is about 0.8. Hence, the total external quantum efficiency of the red luminescent layer and the green luminescent layer is 18.4%. The total external quantum efficiency of the organic electroluminescent apparatus of the example is 20.4% and the color temperature is between about 2500 to 4000K.

Comparing to the high color temperature (5000K) white light emitted from the organic electroluminescent apparatus of comparative example 1, the color temperature of the white light emitted by the organic electroluminescent apparatus of the example may be adjusted by the disposition of a fluorescent layer to attain a white light with a lower color temperature. Moreover, although the organic electroluminescent layer of comparative example 2 can emit a white light with low color temperature (2800K), the organic electroluminescent apparatus of the second exemplary embodiment is unable to totally use the light emitting efficiency of the blue luminescent layer. Hence, the external quantum efficiency of the organic electroluminescent apparatus of comparative example 2 is only 18%. The external quantum efficiency of the example is higher than that of comparative example 2. Alternatively speaking, not only the organic electroluminescent apparatus of the example can provide a white light with a lower color temperature, a more favorable light emitting efficiency is resulted.

According to the organic electroluminescent apparatus of the disclosure, a fluorescent layer is coated on the light emitting side of the organic electroluminescent apparatus. The fluorescent layer can absorb the first color emitted by the first color luminescent layer and transforms it into other colors. Hence, the first color efficiency is reduced while the efficiencies of other colors are enhanced so as to adjust the color temperature of the white light emitted from the organic electroluminescent apparatus. Moreover, the white light color temperature of the organic electroluminescent apparatus of the disclosure can be adjusted according to the type, the thickness and the concentration of the fluorescent material in the fluorescent layer. Further, through the effective application of the light emitting efficiency of the first color luminescent layer, the organic electroluminescent apparatus of the invention having a favorable luminescent efficiency is provided.

It will be apparent to those skilled in the art that various modifications and variations can be made to the structure of the present disclosure without departing from the scope or spirit of the disclosure. In view of the foregoing, it is intended that the present disclosure cover modifications and variations of this disclosure provided they fall within the scope of the following claims and their equivalents.

What is claimed is:

1. An organic electroluminescent apparatus, comprising:
a substrate, wherein the substrate is configured at a first light emitting side of the organic electroluminescent apparatus;
a first electrode layer, configured above the substrate;
a first color luminescent layer, configured above the first electrode layer;
a second color luminescent layer, configured above the first color luminescent layer;
a third color luminescent layer, configured above the second color luminescent layer, wherein a first color light emitted from the first color luminescent layer, a second color light emitted from the second color luminescent layer, and a third color light emitted from the color luminescent layer are mixed to form a white light;
a second electrode layer, configured above the third color luminescent layer; and
a first fluorescent layer, configured on the substrate, wherein the first fluorescent layer is utilized to be excited by the first color light emitted from the first color luminescent layer to emit the second color layer, the third color light or a fourth color light.

2. The organic electroluminescent apparatus of claim 1, wherein the first fluorescent layer is configured on an external surface of the substrate.

3. The organic electroluminescent apparatus of claim 1, wherein the first fluorescent layer is configured on an internal surface of the substrate.

4. The organic electroluminescent apparatus of claim 1, wherein the first fluorescent layer has a thickness of about 0.1 μm to about 1 mm.

5. The organic electroluminescent apparatus of claim 1, wherein a fluorescent material of the first fluorescent layer includes silicate, yttrium aluminum garnet (YAG, Y₃Al₂(AlO₄)₃), green fluorescent powders, red fluorescent powders, lutetium aluminum garnet (LuAG, Lu₃Al₂(AlO₄)₃), or terbium aluminum garnet (TbAG, Tb₃Al₂(AlO₄)₃).

6. The organic electroluminescent apparatus of claim 5, wherein a concentration of the fluorescent material of the first fluorescent material is about 0.1% to 3%.

7. The organic electroluminescent apparatus of claim 1, wherein the second electrode layer is configured at a second light emitting side of the organic electroluminescent apparatus.

8. The organic electroluminescent apparatus of claim 7, further comprising a second fluorescent layer configured on the second electrode layer, wherein the second fluorescent layer is utilized to be excited by the first color light emitted from the first color luminescent layer to emit the second color light, the third color light or the fourth color light.

9. The organic electroluminescent apparatus of claim 1, further comprising a package cover panel, configured at a second light emitting side of the organic electroluminescent apparatus.

10. The organic electroluminescent apparatus of claim 9, further comprising a second fluorescent layer configured on the package cover panel, wherein the second color luminescent layer is utilized to be excited by the first color light emitted from the first color luminescent layer to emit the second color light, the third color light or the fourth color light.

11. The organic electroluminescent apparatus of claim 10, wherein the first fluorescent layer and the second fluorescent layer are constituted with a same type of a fluorescent material.

12. The organic electroluminescent apparatus of claim 8, wherein the second fluorescent layer has a thickness of about 0.1 μm to about 1 mm.

13. The organic electroluminescent apparatus of claim 8, wherein a fluorescent material of the second fluorescent layer includes silicate, yttrium aluminum garnet (YAG, Y₃Al₂(AlO4)₃), green fluorescent powders, red fluorescent powders, lutetium aluminum garnet (LuAG, Lu₃Al₂(AlO₄)₃), or terbium aluminum garnet (TbAG, Tb₃Al₂(AlO₄)₃).

14. The organic electroluminescent apparatus of claim 13, wherein a concentration of the fluorescent material of the second fluorescent layer is about 0.1% to about 3%.

15. An organic electroluminescent apparatus, comprising:
a substrate;
a first electrode layer, configured above the substrate;
a first color luminescent layer, configured above the first electrode layer;
a second color luminescent layer, configured above the first color luminescent layer;
a third color luminescent layer, configured above the second color luminescent layer, wherein a first color light emitted from the first color luminescent layer, a second color light emitted from the second color luminescent layer, and a third color light emitted from the color luminescent layer mix to form a white light;
a second electrode layer configured above the third color luminescent layer and at a light emitting side of the organic electroluminescent apparatus; and
a fluorescent layer, configured on the second electrode layer, wherein the fluorescent layer is utilized to be excited by the first color light emitted from the first color luminescent layer to emit the second color layer, the third color light or a fourth color light.

16. The organic electroluminescent apparatus of claim 15, wherein the fluorescent layer is configured on an external surface of the second electrode layer.

17. The organic electroluminescent apparatus of claim 15, wherein the fluorescent layer is configured on an internal surface of the second electrode layer.

18. The organic electroluminescent apparatus of claim 15, further comprising a package cover panel, configured on the second electrode layer, wherein the fluorescent layer is configured between the second electrode layer and the package cover panel.

19. The organic electroluminescent apparatus of claim 15, further comprising a package cover panel, configured on the second electrode layer, wherein the package cover panel is configured between the second electrode layer and the fluorescent layer.

20. The organic electroluminescent apparatus of claim 15, wherein the fluorescent layer has a thickness of about 0.1 μm to about 1 mm.

21. The organic electroluminescent apparatus of claim 15, wherein a fluorescent material of the fluorescent layer comprises silicate, yttrium aluminum garnet (YAG, Y₃Al₂(AlO4)₃), green fluorescent powders, red fluorescent powders, lutetium aluminum garnet (LuAG, Lu₃Al₂(AlO4)₃), or terbium aluminum garnet (TbAG, Tb₃Al₂(AlO₄)₃).

22. The organic electroluminescent apparatus of claim 21, wherein a concentration of the fluorescent material of the fluorescent layer is about 0.1% to 3%.
